(19) United States
(12) Patent Application Publication
(10) Pub. No.: US 2007/0075433 A1
(43) Pub. Date: Apr. 5, 2007

(54) Semiconductor device having high-density contact holes with oval plane shape arranged to reduce malfunction resulting from bowing during etching

(75) Inventor: Yasuhiko Ueda, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: ELPIDA MEMORY, INC., Tokyo (JP)

(21) Appl. No.: 11/518,278

(22) Filed: Sep. 11, 2006

(30) Foreign Application Priority Data
Sep. 30, 2005 (JP) 2005-287508

(51) Int. Cl. H01L 23/48

(52) U.S. Cl. 257/774

(57) ABSTRACT

A semiconductor device includes a substrate on which a plurality of contact holes, a plane shape of each of which is a oval, are formed and contacts formed in each of the contact holes and having oval-shaped profiles that correspond to each of the holes. The position on the perimeter of each oval at which the separation width with an oval that is adjacent to that oval is a minimum is separated by a prescribed spacing from the intersection of the perimeter of that oval and the minor axis of that oval.

This application is based upon and claims the benefit of priority from Japanese Patent Application No. 2005-287508 filed on Sep. 30, 2005, the content of which is incorporated by reference.

1. Field of the Invention

The present invention relates to a semiconductor device having high-density contacts each having an oval profile, and more particularly to the arrangement of the contacts.

2. Description of the Related Art

In semiconductor devices such as DRAM, the electric charge that accumulates on the capacitors of memory cells is used as an information source. The capacitor comprises a lower electrode, a dielectric mounted on the lower electrode, and an upper electrode mounted on the dielectric; these are arranged in a contact hole. The lower electrode connects with under-layer contact plug that is arranged at a bottom of the contact hole. The under-layer contact plug connects with an active region in the surface of a semiconductor board.

With the trend toward higher integration of semiconductor memory, the contact hole for forming the capacitor is being arranged in higher density. Further, with the trend toward further higher integration and greater miniaturization, demands are growing for high-density contact holes in smaller size and in higher density. A variety of designs have been developed regarding the arrangement and shape of these contact holes in order to respond to these demands.

In DRAM cells having a structure of COB (Capacitor Over Bit line) which is currently in vogue, capacitors are arranged above a bit line via capacitance contact plugs. In this case, the plane shape of the contact hole, in which the capacitor is arranged, is an oval.

However, when a hole having an oval plane shape for forming a contact hole is formed on a thick insulating layer by dry etching, a large degree of bowing occurs on the minor axis side even when the difference between the major axis and minor axis is slight. Bowing refers to a phenomenon in which the excessive progression of etching in a portion in the side-wall direction of the hole causes a concave shape in the side walls. This bowing is attended by a phenomenon in which the diameter of the hole bottom is reduced in the direction of the minor axis.

It turned out that bowing tends to occur in the direction of the minor axis when etching holes in silicon oxide, particularly etching holes in a pattern having a high aspect ratio, as in forming this type of contact. In contrast, bowing tends not to occur in the major axis direction. This distortion is believed to occur because the orbits of the ions for etching are distorted by the charge of the mask for hole formation, whereby etching is accelerated. In other words, it is believed that the orbits of ions tend to be distorted in the direction of the minor axis in which the mask is narrow, whereby bowing tends to occur in the direction of the minor axis. It is further believed that, due to the distortion of the orbits of ions, sufficient energy fails to reach the bottoms of holes and thus reduces the diameter in the direction of the minor axis.

Bowing also occurs in contacts having a circular plane shape, and methods have been proposed for preventing this occurrence. In JP-A-H08-191062, dry etching is carried out in two stages. Isotropic dry etching is first carried out as far as midway through the direction of film thickness of the dielectric, and anisotropic dry etching is then carried out to the end of the dielectric. In JP-A-2005-229052, anisotropic dry etching is first carried out as far as midway through the interlayer dielectric under the condition of low etching selectivity of the photoresist and interlayer dielectric. Anisotropic dry etching is next carried out as far as the electrical connection region or the electrical wiring of the active elements under the condition of high etching selectivity of the photoresist and interlayer dielectric. Alternatively, in JP-A-2004-335526, the first etching is halted at a depth at which bowing does not occur to form holes. An etching protection film is next formed in portions of the side walls of these holes at which bowing is expected to occur when progressing further in the formation of holes. The second etching is then carried out to form the holes to the prescribed depth. Fine holes having an aspect ratio of 13 or more are formed by this method.

The methods for restricting bowing described in the previously mentioned patent documents take as object contacts having a circular outer shape, and the steps of these methods are complicated, thereby reducing accuracy of control in forming a hole. Due to these factors, these methods are not used for high-density contacts having an oval profile in semiconductor devices, and in particular, high-density contacts for DRAM capacitors.

FIG. 1 is a plan view showing the arrangement of contact holes for forming high-density contacts of a semiconductor device in the related art. FIG. 2 is a plan view-showing the state at the position of the depth of the contact holes of FIG. 1 in which bowing occurs, and FIG. 3 is a sectional view taken along the A-A profile of FIG. 1. Each figure is a schematic figure based on an SEM (Scanning Electron Microscope) photograph of a fabrication example that is to be described.

As shown in FIG. 1, in the layout 5 of contact holes 50 for forming contacts in the related art, ovals aligned in the same direction are aligned in regular rows. As described hereinabove, it is demanded that high-density contacts, and in particular, high-density contacts for DRAM capacitors, be formed in a pattern that is as highly concentrated as possible, and that each contact hole 50 be arranged at fine intervals in both the direction of minor axis 52 and the direction of major axis 51. In this layout, the separation width between adjacent contact holes 50 is substantially the minimum distance (minimum separation width 56) between the intersections between minor axes 52 and the perimeters of contact holes 50.

In the present specification, the separation width means the thickness of the walls composed of the remaining portion of substrate between adjacent contact holes 50, and consequently, between contacts that are formed inside contact holes 50. The minimum separation width refers to the thickness of the portions of these walls that-are thinnest. In this context, the separation width and the minimum separation width do not include the influence of bowing.

As shown in FIG. 2 and FIG. 3, in contact holes 50 that are formed by etching, a relatively high degree of bowing occurs in the direction of minor axes 52, and thus, at the points of minimum separation width 56. As a result, when contact holes 50 in this layout are etched, there is a high risk for the occurrence of shorts between adjacent contact holes 50.

The following explanation regards hole layout 5 for high-density contacts of a semiconductor device of the related art and the state of occurrence of bowing by way of a specific fabrication example. In this fabrication example, minor axis 52 of the oval profile of contact holes 50 is 204 nm, major axis 51 is 240 nm, and minimum separation width 56 is 67 nm (dimensions in the mask pattern). The vertical structure of the substrate and mask by which contact holes 50 are formed is: Poly-Si mask (800 nm)/P-TEOS (3000 nm)/P-SiN (50 nm). When etching SiO₂, a two-frequency parallel plate RIE (Reactive Ion Etching) device is used, and processing is carried out in an atmosphere of C₄F₆/Ar/O₂ gas at 25 mTorr. For SiN etching, the same device was used and processing was carried out in an atmosphere of CHF₃/Ar/O₂ gas at 25 mTorr. In the interest of appraising shorts between adjacent contact holes 50, 20% overetching was carried out in the etching of SiO₂.

Contact holes 50 were processed to a depth of 3000 nm under these conditions. Here, bowing occurred at positions at a depth of approximately 250 nm as shown schematically in FIG. 3 (bowing portion 55). Bowing portion 55 in each of contact holes 50 occurs at substantially the same position in the direction of depth. As shown schematically in FIG. 2, which shows the state after abrading the surface to the position of the depth of this bowing portion 55, a higher degree of bowing occurs in the direction of minor axis 52 than the direction of major axis 51. The extent of bowing was 30 nm on one side in the direction of minor axis 52 and 8 nm on one side in the direction of major axis 51. After etching, the wall thickness between adjacent contact holes 50 was 7 nm at the points of bowing portions 55, and it can thus be seen that almost no margin remains for preventing the occurrence of shorts between adjacent contact holes 50.

As can be seen from the above-described fabrication example, generally, when contact holes 50 for oval contacts are formed by dry etching, as a result of the nature of dry etching, conspicuous bowing is apparent in the direction of minor axis 52 even though almost no bowing occurs in the direction of major axis 51. Thus, in an arrangement in which the distance between side surfaces in the direction of minor axis 52 of contact holes 50 is the minimum separation width 56, the wall thickness between adjacent contact holes 50 is extremely small at the positions of bowing portions 55. In other words, in such an arrangement, positions where walls that separate adjacent contact holes 50 are thinnest are subject to a relatively high degree of reduction due to bowing, and there is consequently a high danger of shorts between contact holes 50 at these reduced portions.

### SUMMARY OF THE INVENTION

It is an object of the present invention to provide a semiconductor device having high-density contacts that have an oval profile wherein the semiconductor device, without necessitating a special etching step, enables a suppression of the occurrence of shorts between adjacent contact holes despite the occurrence of bowing.

This semiconductor device of the present invention includes a substrate on which a plurality of contact holes, a plane shape of each of which is a oval, are formed, and in each contact hole a contact is formed having an oval profile that corresponds to the contact hole. The position on the perimeter of at least one of oval at which the separation width between that oval and an adjacent oval is a minimum is separated by at least a prescribed spacing from the intersection between the perimeter of that oval and the minor axis of that oval.

The prescribed spacing is preferably equal to a distance corresponds to a sum of a maximum growth width of bowing at an intersection between the perimeter of said oval and a minor axis of that oval, and a maximum growth width of bowing at position on the perimeters of adjacent said oval at which the separation width between adjacent said ovals is a minimum.

A position on a perimeter of each of said ovals at which a separation width between said oval and an adjacent said oval is a minimum is preferably separated from an intersection between the perimeter of that oval and a minor axis of that oval

The extended line of the minor axis of each oval preferably does not intersect with the perimeter of the oval that is closest to that oval.

The above-described arrangement of ovals can be realized by adjusting the direction of the major axes or minor axes of the ovals. In particular, the extended lines of the minor axes of a pair of ovals arranged above the same active region preferably intersect at an angle of at least 45°.

The contact holes may constitute holes in each of which a capacitor for DRAM is arranged.

Thus, despite the occurrence of bowing at the time of etching in holes for forming oval-shaped contacts, the present invention can suppress the reduction of wall thickness between contacts caused by this bowing. The present invention can therefore suppress the occurrence of shorts between adjacent contacts, and further, shorten the distance between contacts while suppressing the occurrence of shorts to thus raise the density of the arrangement of contacts.

The above and other objects, features and advantages of the present invention will become apparent from the following description with reference to the accompanying drawings which illustrate examples of the present invention.

### BRIEF DESCRIPTION OF THE DRAWINGS

FIG. 1 is a schematic plan view showing the arrangement of contact holes for forming high-density confacts of a semiconductor device of the related art;

FIG. 2 is a schematic plan view showing the state at the position of the depth at which bowing occurs in the contact holes of FIG. 1;

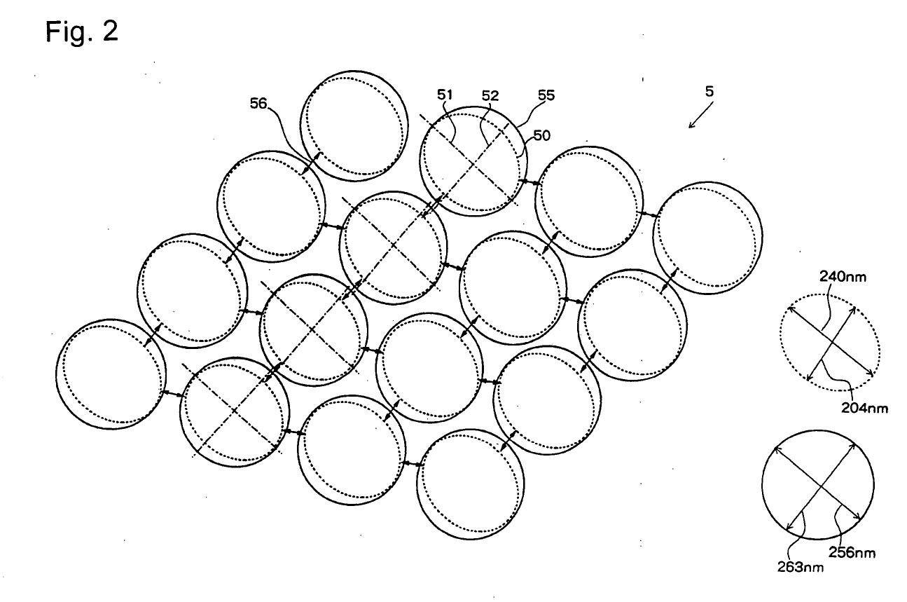

FIG. 3 is a sectional view of contact holes at the A-A section of FIG. 1;

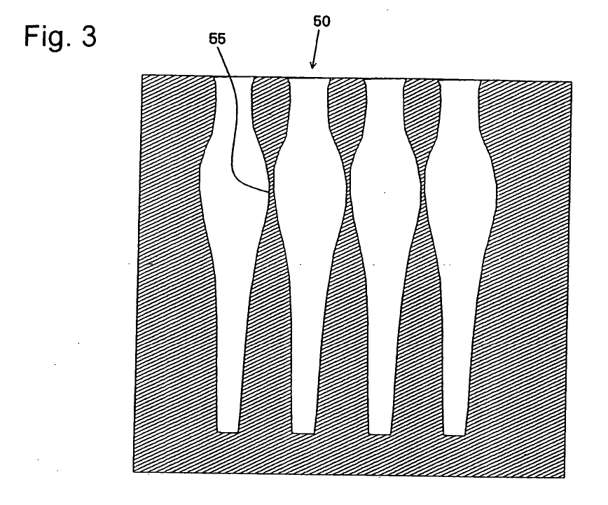

FIG. 4 is a schematic plan view showing the arrangement of contact holes for forming high-density contacts of a semiconductor device according to the first embodiment of the present invention;

FIG. 5 is a schematic plan view showing the state at the position of the depth at which bowing occurs in the contact holes of FIG. 4;

FIG. 6 is a schematic plan view showing the arrangement of contact holes for forming high-density contacts of a semiconductor device according to the second embodiment of the present invention; and

FIG. 7 is a schematic plan view showing the state at the position of the depth at which bowing occurs in the contact holes of FIG. 6.

### DETAILED DESCRIPTION OF THE PREFERRED EMBODIMENTS

In the present invention, in response to the above-described problems, layout is realized in accordance with the following two principles: (1) the separation width between contact holes is not to become a minimum between side surfaces in the direction of the minor axes; (2) contact holes are to be arranged such that the separation width between contact holes becomes a minimum between side surfaces as close as possible to the direction of the major axes. In this way, the present invention can realize processing that limits the reduction of the margin for suppressing shorts between contact holes, this reduction being caused by bowing at the time of etching. In particular, the present invention, to the greatest possible extent, makes those positions at which the separation width between adjacent contact holes becomes a minimum the positions in the direction of the major axis in which virtually no bowing occurs and thus enables a marked increase in the margin for suppressing shorts.

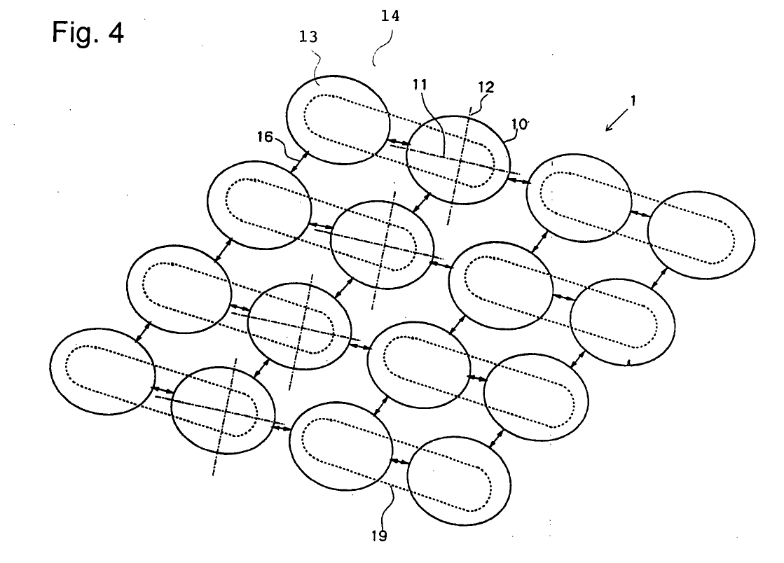

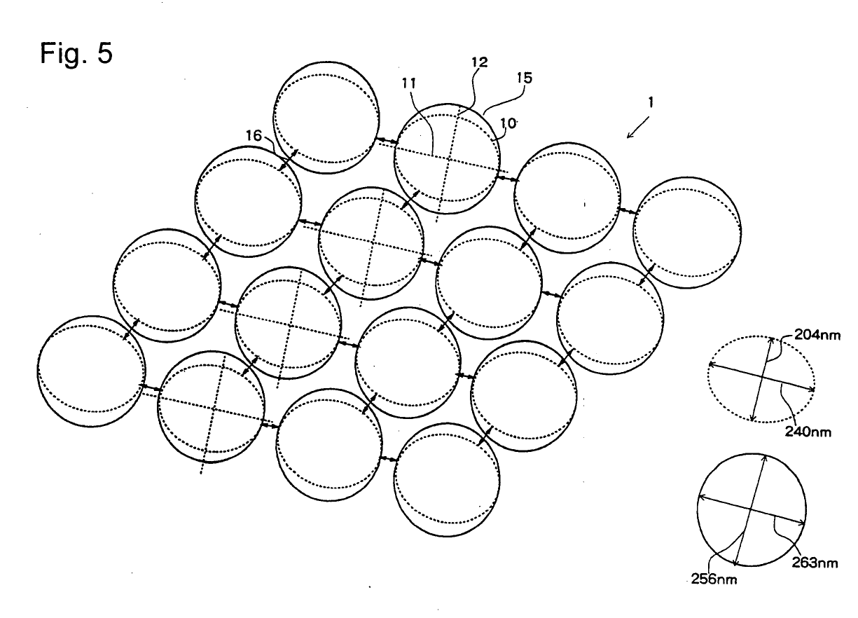

FIG. 4 is a schematic plan view showing the arrangement of contact holes 10 for forming high-density contacts of a semiconductor device according to the first embodiment of the present invention. FIG. 5 is a schematic plan view showing the state at positions at the depth at which bowing occurs in contact holes 10 of FIG. 4. In each embodiment, explanation regards contact holes 10 formed in substrate 14 for forming contacts 13. Contacts 13 are formed in these contact holes 10 in a subsequent step. The formation of these contacts 13 can be realized by a known method, and explanation of the details of this process is therefore omitted. Contacts 13 are formed pair by pair on each active region 19, and the density of these contacts 13 is maximized, i.e., these contacts are arranged in a dense arrangement.

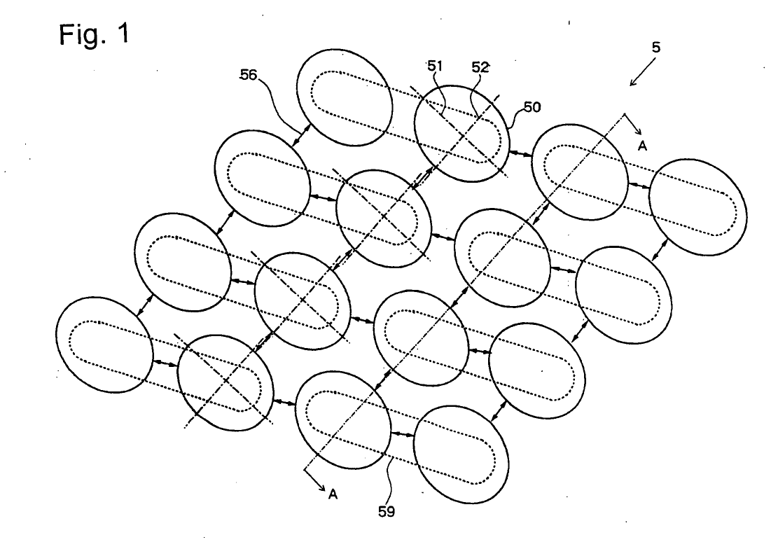

Hole layout 1 for high-density contacts in the present embodiment shown in FIG. 4 is an arrangement designed to increase the margin for suppressing shorts between adjacent contact holes 10. Compared to the layout of the related art shown in FIG. 1, each of contact holes 10 in this layout has been rotated 30° counterclockwise. As a result, the intersection between the perimeter of each contact hole 10 and minor axis 12 is distanced from the positions at which the separation width between the perimeter of that contact hole 10 and an adjacent contact hole 10 becomes minimum separation width 16. Further, as a result of rotating each contact hole 10 in the example shown in FIG. 4, the extended line of minor axis 12 of each of contact holes 10 does not intersect with the perimeter of contact hole 10 that is adjacent (that is closest) to that contact hole 10. Accordingly, the greatest amount of bowing in the direction of the minor axis of each contact hole 10 does not contribute to the reduction of the wall thickness between contacts 13.

When the dimensions of each contact hole 10 and the distance between the center points of each contact hole 10 are identical to those in the related art, minimum separation width 16 in the present embodiment is 58 nm, which is slightly smaller than in the related art.

Bowing occurs at positions at a depth of approximately 250 nm after processing contact holes 10 to a depth of 3000 nm, as in the related art; and FIG. 5 shows the state after surface abrasion to this depth. As in the related art, when forming oval-plane-shaped contact holes 10 with a minor axis of 204 nm and a major axis of 240 nm, the extent of bowing is 30 nm in the direction of minor axis 12 and 8 nm in the direction of major axis 11. As a result, after etching, the wall thickness between contact holes 10 was 10 nm at positions in which bowing occurred. In other words, after etching, the wall thickness between contact holes 10 at positions at which bowing occurred can be increased to more than the thickness of 7 nm in the related art, and as a result, the margin for suppressing shorts between contact holes 10 can be similarly increased.

The present embodiment thus enables an increase in the minimum wall thickness between contact holes 10 when the distance between the center points of contact holes 10, i.e., the degree of density of contacts 13 or arrangement density, is made the same as in the related art. As a result, the present embodiment can suppress the occurrence of shorts, and further, raise the arrangement density of contacts 13 while taking into consideration the fabrication error to ensure sufficient wall thickness to enable suppression of the occurrence of shorts. In this time, in order to achieve the maximum possible increase in arrangement density while ensuring sufficient wall thickness to enable suppression of the occurrence of shorts, a spacing from a position on a perimeter of contact hole 10, at which a separation width between that contact hole 10 and an adjacent contact hole 10 is a minimum, to an intersection between the perimeter of that contact hole 10 and a minor axis of that contact hole 10, is preferably set to a distance corresponds to a sum of a maximum growth width of bowing at an intersection between the perimeter of that contact hole 10 and a minor axis of that contact hole 10, and a maximum growth width of bowing at position on the perimeters of adjacent contact hole 10 at which the separation width between adjacent contact holes 10 is a minimum.

In the present embodiment, a configuration was shown in which, for all contact holes 10, the intersections between the perimeters and minor axes 12 are positioned sufficiently far from positions on the perimeters corresponding to minimum separation width 16. However, when a relatively large spacing can be ensured between a number of contacts 13, the intersections between the perimeters and minor axes 12 for these contacts 13 may coincide with the positions on the perimeters that correspond to minimum separation width 16. In this case, minimum separation width 16 between these contacts 13 is preferably set to a distance obtained by multiplying a prescribed safety factor by twice the maximum growth width of bowing that is expected to occur in the direction of the minor axes of contact holes 10.

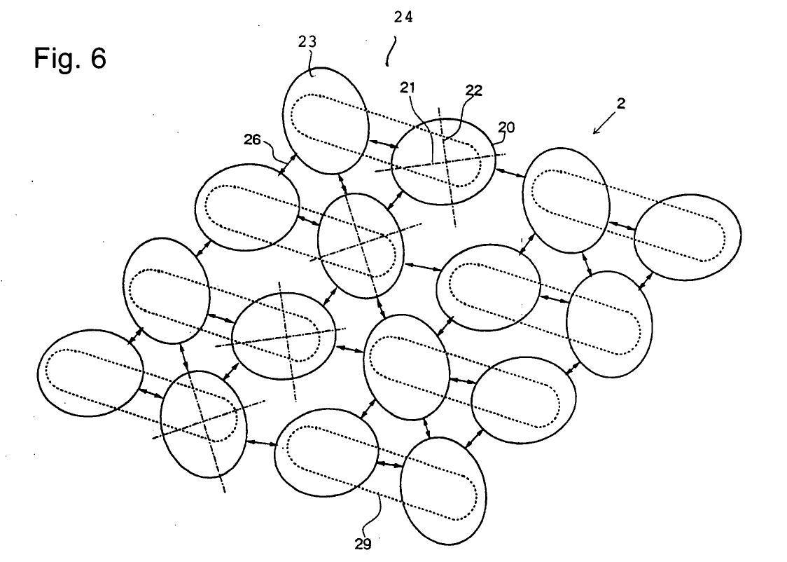

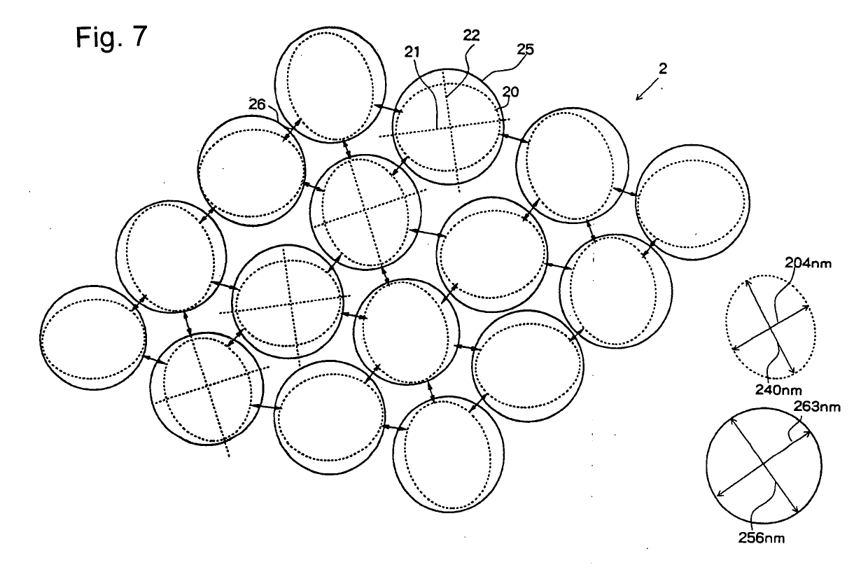

FIG. 6 is a schematic plan view showing the arrangement of contact holes 20 for forming high-density contacts, these contact holes 20 being formed in substrate 24 of a semiconductor device of the second embodiment of the present invention; and FIG. 7 is a schematic plan view showing the state at the position of the depth at which bowing occurs in contact holes 20 of FIG. 6.

Hole layout 2 for high-density contacts in the present embodiment shown in FIG. 6 is a layout devised for enlarging the margin for suppressing shorts between adjacent contact holes 20. This layout is basically a layout in which the orientation of each contact hole 20 is adjusted such that the distance between positions in the direction of the major axes on the perimeters of adjacent contact holes 20, or the distance between positions close to the direction of the major axes is minimum separation width 26 of adjacent contact holes 20. As a result, the maximum possible spacing is ensured for the spacing from the side surfaces in the direction of the minor axes of each contact hole 20 to adjacent contact hole 20. Hole layout 2 for high-density contacts of the example shown in FIG. 6 is a repeating pattern in which, taking four contact holes 20 aligned in substantially the horizontal direction of the figure as one set, sets of two types, each type having a different pattern of orientation of contact holes 20, are arranged alternately in substantially the vertical direction of the figure. In this case, the extended lines of minor axes 22 of contact holes 20 for a pair of contacts 23 formed on an independent active region 29 intersect at an angle of at least 45° . In this case, minimum separation width 26 is 58 nm, which is slightly less than in the related art.

As in the related art, after contact holes 20 have been processed to a depth of 3000 nm, bowing occurs at positions at a depth of approximately 250 nm, and FIG. 7 shows the state after surface abrasion to this depth. As in the example of the related art, when oval holes are formed with a minor axis of 204 nm and major axis of 240 nm, the extent of bowing is 30 nm in the direction of minor axis 22 and 8 nm in the direction of major axis 21. As a result, after etching, the wall thickness between contact holes 20 at positions where bowing occurs is 20 nm. The present embodiment is thus able to increase the wall thickness between contact holes 20 at positions where bowing occurs after etching to a greater thickness than the 10 nm in the first embodiment and the 7 nm in the related art. In the present embodiment, the minimum wall thickness is substantially twice that of the related art, and the margin for suppressing shorts is greatly improved. These effects are obtained because the separation width between contact holes 20 is a minimum only between side surfaces close to the direction of the major axes, where bowing is slight.

Although explanation has been given for two embodiments, the first and second embodiments, the present invention is not limited to these forms, and as previously explained, the present invention is based on the two principles: (1) contact holes are to be arranged such that the separation width between contact holes is not a minimum between side surfaces in the direction of minor axes; (2) contact holes are to be arranged such that the separation width between contact holes is a minimum between side surfaces as close as possible to the direction of major axes. By means of these principles, processing can be realized that decreases the reduction of the margin for suppressing shorts between contact holes, this reduction being caused by the bowing that occurs in etching. In particular, as in the second embodiment, the margin for suppressing shorts can be greatly increased by adopting an arrangement such that, to the greatest extent possible, the separation width between contact holes is a minimum between side surfaces close to the direction of the major axes, at which virtually no bowing occurs.

The adoption of this type of layout enables processing of high-density contacts having a high aspect ratio, and in particular, high-density contacts for DRAM capacitors, which demand fine and precise processing, while suppressing malfunction that results from bowing.

While preferred embodiments of the present invention have been described using specific terms, such description is for illustrative purposes only, and it is to be understood that changes and variations may be made without departing from the spirit or scope of the following claims.

What is claimed is:

1. A semiconductor device comprising:
a substrate on which a plurality of contact holes, a plane shape of each of which is a oval, are formed; and
contacts formed in each of said contact holes, said contacts having an oval profile that corresponds to each of said contact holes;
wherein a position on a perimeter of at least one of said ovals at which a separation width between said oval and an adjacent said oval is a minimum is separated by at least a prescribed spacing from an intersection between the perimeter of that oval and a minor axis of that oval.

2. A semiconductor device according to claim 1, wherein said prescribed spacing is equal to a distance corresponds to a sum of a maximum growth width of bowing at an intersection between the perimeter of said oval and a minor axis of that oval, and a maximum growth width of bowing at position on the perimeters of adjacent said oval at which the separation width between adjacent said ovals is a minimum, said bowing being the bowing that occurs in said contact hole when forming said contact holes by etching.

3. A semiconductor device according to claim 1, wherein a position on a perimeter of each of said ovals at which a separation width between said oval and an adjacent said oval is a minimum is separated from an intersection between the perimeter of that oval and a minor axis of that oval.

4. A semiconductor device according to claim 1, wherein an extended line of the minor axis of each said oval does not intersect with the perimeter of said oval that is closest to that oval.

5. A semiconductor device according to claim 1, wherein:
a plurality of separated active regions are formed in said substrate;
a pair of said contact holes are arranged above each of said active regions; and
an extended lines of the minor axes of a pair of said contacts arranged above the same said active region intersect at an angle of at least 45°0 .

6. A semiconductor device according to claim 1, wherein said contact holes constitute holes in each of which a capacitor for DRAM is arranged.
